(19) United States
(12) Patent Application Publication
(10) Pub. No.: US 2012/0111263 A1
(43) Pub. Date: May 10, 2012

(54) METHOD FOR THE DETERMINATION OF IMPURITIES IN SILICON

(75) Inventor: Kurt BONAUER-KLEPP, Burghausen (DE)

(73) Assignee: WACKER CHEMIE AG, Muenchen (DE)

(21) Appl. No.: 13/289,485

(22) Filed: Nov. 4, 2011

(30) Foreign Application Priority Data
Nov. 10, 2010 (DE) 10 2010 043 702.6

(51) Int. Cl. C30B 13/00

(52) U.S. Cl. 117/38

(57) ABSTRACT

The invention relates to a method for the determination of impurities in silicon, in which a monocrystalline rod is produced by means of zone refining from a silicon to be tested; this monocrystalline rod is introduced, in at least one dilution step, into a casing made of mono- or polycrystalline silicon having defined carbon and dopant concentrations and a diluted monocrystalline rod of silicon is produced from the rod and casing by means of zone refining; wherein the determination of impurities in the silicon to be tested is carried out with the aid of a diluted monocrystalline rod by means of photoluminescence or FTIR or both.

### BACKGROUND OF THE INVENTION

The invention relates to a method for the determination of impurities in silicon.

On the industrial scale, raw silicon is obtained by the reduction of silicon dioxide with carbon in an arc furnace at temperatures of about 2000° C.

So-called metallurgical silicon (Si_{mg}, “metallurgical grade”) with a purity of about 98-99% is thereby obtained.

For applications in photovoltaics and microelectronics, the metallurgical silicon needs to be purified.

To this end, for example, it is reacted with gaseous hydrogen chloride at 300-350° C. in a fluidized bed reactor to form a gas containing silicon, for example trichlorosilane.

This is followed by distillation steps, in order to purify the gas containing silicon.

This gas containing highly pure silicon is then used as a starting material for the production of highly pure polycrystalline silicon.

The polycrystalline silicon, often also abbreviated to polysilicon, is conventionally produced by means of the Siemens process. In this case, thin filament rods of silicon are heated by direct passage of current in a bell-shaped reactor (“Siemens reactor”) and a reaction gas comprising a silicon-containing component and hydrogen is introduced.

During the Siemens process, the filament rods are conventionally fitted vertically into electrodes located on the bottom of the reactor, via which the connection to the electricity supply is established. Respective pairs of filament rods are coupled by means of a horizontal bridge (likewise made of silicon) and form a support body for the silicon deposition. The typical U-shape of the support bodies, also referred to as thin rods, is produced by the bridge coupling.

Highly pure polysilicon is deposited on the heated rods and the bridge, so that the rod diameter increases with time (CVD=chemical vapor deposition).

After the end of the deposition, these polysilicon rods are conventionally processed further by means of mechanical processing to form chunks of different size classes, optionally subjected to wet chemical cleaning and finally packaged.

The polysilicon may, however, also be processed further in the form of rods or rod segments. This applies in particular for use of the polysilicon in FZ methods.

The silicon-containing component of the reaction gas is generally monosilane or a halosilane with the general composition SiHₙX₄₋ₙ, (n=0, 1, 2, 3; X=Cl, Br, I). It is preferably a chlorosilane, particularly preferably trichlorosilane. SiH₄ or SiHCl₃ (trichlorosilane, TCS) in a mixture with hydrogen is predominantly used.

Besides this, it is also known to expose small silicon particles directly to such a reaction gas in a fluidized bed reactor. The polycrystalline silicon thereby produced has the form of granules (granular poly).

Polycrystalline silicon (abbreviation: polysilicon) is used as a starting material for the production of monocrystalline silicon by means of crucible pulling (Czochralski or CZ method) or by means of zone melting (float zone or FZ method). This monocrystalline silicon is cut into wafers and, after a multiplicity of mechanical, chemical and chemical-mechanical processing operations, is used in the semiconductor industry to fabricate electronic components (chips).

In particular, however, polycrystalline silicon is required to an increased extent for the production of monocrystalline or polycrystalline silicon by means of pulling or casting methods, this monocrystalline or polycrystalline silicon being used to fabricate solar cells for photovoltaics.

Since the quality requirements for polysilicon are becoming ever higher, quality controls throughout the process chain are indispensable. The material is tested, for example, for contamination with metals or dopants. Distinction is to be made between bulk contamination and surface contamination of the polysilicon chunks or rod segments.

It is also conventional for the polysilicon produced to be converted into monocrystalline material for the purpose of quality control. In this case, the monocrystalline material is tested. Here again, metal contaminations, which are to be regarded as particularly critical for customer processes in the semiconductor industry, are particularly important. The silicon is, however, also tested for carbon as well as dopants such as aluminum, boron, phosphorus and arsenic.

Dopants are analyzed according to SEMI MF 1398 on an FZ single crystal produced from the polycrystalline material (SEMI MF 1723) by means of photoluminescence. As an alternative, low-temperature FTIR (Fourier transform IR spectroscopy) is employed (SEMI MF 1630). FTIR (SEMI MF 1188, SEMI MF 1391) makes it possible to determine carbon and oxygen concentrations.

The fundamentals of the FZ method are described, for example, in DE-3007377 A.

In the FZ method, a polycrystalline feed rod is gradually melted with the aid of a radiofrequency coil and the molten material is converted into a single crystal by seeding with a monocrystalline seed crystal and subsequent recrystallization. During the recrystallization, the diameter of the resulting single crystal first increases conically (cone formation) until a desired final diameter is reached (rod formation). In the cone formation phase, the single crystal is also mechanically supported in order to relieve the load on the thin seed crystal.

It has, however, been found that polycrystalline silicon with high extrinsic substance concentrations and highly contaminated material, for example processed metallurgical silicon (“upgraded metallurgical grade”, UMG), which was converted into an FZ single crystal cannot readily be analyzed by means of photoluminescence or FTIR. The contaminations are too high for the range measurable by means of photoluminescence or FTIR. For dopants, concentrations of the order of ppta can be measured by PL (photoluminescence), and for carbon concentrations of the order of ppba can be measured by FTIR.

DE 41 37 521 B4 describes a method for analyzing the concentration of impurities in silicon particles, characterized in that particulate silicon is placed in a silicon vessel, the particulate silicon and the silicon vessel are processed to form monocrystalline silicon in a floating zone and the concentration of impurities, which are present in the monocrystalline silicon, is determined.

It is regarded as advantageous in this method that the sample is contaminated minimally by the method. The particulate silicon is intended to be of electronics quality or an equivalent quality. The particulate silicon may be polycrystalline or monocrystalline particles or fragments.

If the silicon to be tested is already of electronics quality, the problems observed in the prior art with photoluminescence measurements do not arise since the contaminations are at a sufficiently low level. Here, it is paramount that a different shape, namely a rod shape, can be imparted to the particulate silicon by the float zone method in order to be able to carry out such measurements.

A disadvantage with the method is that there must be sufficient contact between the particles and the silicon vessel, in order to ensure sufficient heat transfer. This entails the risk that the silicon to be analyzed will become contaminated.

The object of the invention resulted from the described problems.

### DESCRIPTION OF THE INVENTION

The object is achieved by a method for the determination of impurities in silicon, in which a monocrystalline rod is produced by means of zone refining from silicon to be tested; this monocrystalline rod is introduced, in at least one dilution step, into a casing made of mono- or polycrystalline silicon having defined carbon and dopant concentrations and a diluted monocrystalline rod of silicon is produced from the rod and casing by means of zone refining; wherein the determination of impurities in the silicon to be tested is carried out with the aid of a diluted monocrystalline rod by means of photoluminescence or FTIR or both.

Preferably, the silicon to be tested has a carbon content of at least 1 ppma and a dopant content of at least 1 ppba before the at least one dilution step.

Preferably, after the at least one dilution step, further dilution steps are carried out with a further casing made of mono- or polycrystalline silicon having defined carbon and dopant concentrations and the new monocrystalline rod of silicon respectively obtained after the preceding dilution step, in order to produce a diluted monocrystalline silicon rod.

Preferably, further dilution steps are carried out until the diluted silicon rod has a carbon content of less than 1 ppma and a dopant content of less than 1 ppba.

The starting point of the method is processed metallurgical silicon or polycrystalline silicon, which is contaminated with carbon and with dopants. The material is contaminated with carbon and/or dopants in such a way that a measurement of the impurities by means of photoluminescence is not initially possible.

The starting material is preferably in the form of a thin rod, as obtained after deposition on a filament rod in a Siemens reactor.

A single crystal is grown from this thin rod by means of FZ (float zone) zone refining.

This monocrystalline rod has a circular cross section and preferably a diameter of from 2 to 35 mm.

Before the final diameter of from 2 to 35 mm is reached during the FZ growth, a so-called thin neck is preferably pulled in order to achieve dislocation-free growth and obtain a suitable rod as a filler of the casing for the dilution step.

The monocrystalline rod grown from the starting material is subsequently introduced into a casing made of monocrystalline or polycrystalline silicon.

The monocrystalline (or polycrystalline) rod, which is contained in the silicon casing, is then converted into a monocrystalline rod by means of FZ. Here again, a so-called thin neck is preferably pulled in order to achieve dislocation-free growth and obtain a suitable rod as a filler of the casing for the subsequent dilution step.

Preferably, the internal diameter of the casing corresponds approximately to the diameter of the monocrystalline rod previously produced.

It is, however, also possible and particularly preferable for the rod diameter to be less than the internal diameter of the casing.

Specifically, it has been found that dislocation-free growth is possible even if there is a gap between the internal wall of the casing and the outer surface of the monocrystalline rod.

Preferably, there is no contact between the casing and the cylindrical crystal. The fact that such an arrangement provides a defect-free single crystal, which may also be used as the starting material for further dilution steps, is surprising.

If there is no contact between the casing and the cylindrical crystal, any mechanical processing of the cylindrical crystal can furthermore be obviated. This is advantageous not least since such mechanical processing could always constitute a cause of additional contamination.

The silicon casing may be produced from a mono- or polycrystalline rod by boring it out.

By producing a new monocrystalline rod from the original monocrystalline (or polycrystalline) rod and the silicon casing, it is possible to dilute the concentration of extrinsic substances in the silicon.

The mono- or polycrystalline material of the casing has a defined level of contamination with carbon and dopants. The concentration of impurities in the silicon casing is ideally at a much lower level than the concentration in the silicon to be tested.

Dilution of the impurities is therefore achieved by the growth of a new rod from the casing and the original rod.

It is also preferable to carry out such a dilution step several times.

In the case of highly contaminated starting material, such repeated dilution operations are absolutely necessary in order to reach the ranges which can be measured by means of photoluminescence.

This can be done by introducing the monocrystalline rod obtained after the first dilution step again into a silicon casing and subjecting the rod/casing to an FZ process once more.

Further dilution of the concentration of impurities is achieved by each additional dilution step.

If the concentration of impurities is already at a level which permits determination of the concentration by means of photoluminescence after the first dilution step, no further dilution step is preferably carried out.

The concentration of impurities is then at a level which permits determination of the concentration by means of photoluminescence when the carbon content is less than 1 ppma and the dopant content is less than 1 ppba.

When determining the concentrations by means of photoluminescence, the dilution must of course be taken into account. Yet since the degree of contamination of the material of the silicon casing is known, i.e. it lies in the range which can be measured by means of photoluminescence, it is no problem for the person skilled in the art to determine the exact concentration of the contamination in the silicon to be tested by means of the concentration of the impurities in the single crystal produced from (rod/casing), or after n dilution steps in the single crystal produced from (rod/n*casing).

In the case of high crystal growth rates of more than 10 mm/min, which is preferred, segregation may be neglected to first approximation since high segregation coefficients occur. The cylindrical single crystal used, which preferably has a crystal diameter of 2-35 mm, is preferably produced with such a high pulling rate and low effective melt height. For boron and phosphorus, virtually no segregation effects then take place, which makes the method less complicated, all the more so since segregation effects have always had to be taken into account in the prior art (SEMI MF 1723-1104).

It has been found that the method permits quantification of the doping elements by the photoluminescence method even with unlimitedly high dopant concentrations.

### EXAMPLES

Rod-shaped samples of polycrystalline silicon and metallurgical silicon were tested.

The samples had a diameter of about 5 mm.

Monocrystalline rods with a diameter of about 12 mm were grown from these samples by means of FZ.

Undoped polycrystalline silicon casings (diameter about 19 mm) were used as casings.

4 dilution steps were carried out.

After the first three dilution steps, the concentrations of boron and phosphorus were not in the measurable range.

After the fourth dilution step, the concentrations of the dopants were in the measurable range.

For this purpose, a measurement wafer was taken from a defined position of the single crystal and was subjected to photoluminescence measurements.

79 ppta of phosphorus and 479 ppta of boron were found.

The concentrations of the original samples could be found therefrom. 1.0 ppma of phosphorus and 6.3 ppma of boron were found.

With respect to carbon, its concentration already lay in the measurable range after the third dilution. It was 87 ppba.

For the original sample, 833 ppma of carbon were calculated.

What is claimed is:

1. A method for determining impurities in silicon, comprising:
zone refining the silicon to produce a monocrystalline rod;
conducting at least one dilution step to introduce the monocrystalline rod into a casing comprising mono- or polycrystalline silicon having defined carbon and dopant concentrations;
zone refining the monocrystalline rod and the casing to produce a diluted monocrystalline rod of silicon; and
conducting at least one of photoluminescence and FTIR on the diluted monocrystalline rod of silicon to determine impurities in the silicon.

2. The method as claimed in claim 1, wherein the silicon to be tested has a carbon content of at least 1 ppma and a dopant content of at least 1 ppba before the at least one dilution step.

3. The method as claimed in claim 2, wherein after the at least one dilution step, further dilution steps are carried out with a further casing comprising mono- or polycrystalline silicon having defined carbon and dopant concentrations and a new monocrystalline rod of silicon respectively obtained after the preceding dilution step, in order to produce a diluted monocrystalline silicon rod.

4. The method as claimed in claim 3, wherein dilution steps are carried out until the diluted silicon rod has a carbon content of less than 1 ppma and a dopant content of less than 1 ppba.

5. The method as claimed in claim 1, wherein after the at least one dilution step, further dilution steps are carried out with a further casing comprising mono- or polycrystalline silicon having defined carbon and dopant concentrations and a new monocrystalline rod of silicon respectively obtained after the preceding dilution step, in order to produce a diluted monocrystalline silicon rod.

6. The method as claimed in claim 5, wherein dilution steps are carried out until the diluted silicon rod has a carbon content of less than 1 ppma and a dopant content of less than 1 ppba.
